(19) United States
(12) Patent Application Publication
(10) Pub. No.: US 2021/0396697 A1
(43) Pub. Date: Dec. 23, 2021

(54) HUMIDITY SENSOR INCORPORATING AN OPTICAL WAVEGUIDE

(71) Applicants: Stefan Jessenig, Eindhoven (NL); Victor Sidorov, Eindhoven (NL)

(72) Inventors: Stefan Jessenig, Eindhoven (NL); Victor Sidorov, Eindhoven (NL)

(21) Appl. No.: 17/289,541

(22) PCT Filed: Oct. 30, 2019
(86) PCT No.: PCT/EP2019/079731

§ 371 Date: Apr. 28, 2021

Related U.S. Application Data
(60) Provisional application No. 62/754,195, filed on Nov. 1, 2018.

(51) Int. Cl. G01N 25/68; G01N 21/552

(52) U.S. Cl. CPC G01N 25/68; H01L 35/02; G01N 21/552

(57) ABSTRACT

A humidity sensor system (10) includes a monolithically integrated semiconductor device (12). The monolithically integrated semiconductor device (12) includes an optical waveguide (14), a thermo-electric cooling device (16), a temperature measurement probe (18), and control circuitry (26) operable to cause the thermo-electric cooling device (16) to adjust a temperature of the monolithically integrated semiconductor device (12). The optical waveguide (14) is operable to receive an input optical signal from a light source (20) and to provide an output optical signal for sensing by a light detector (22). The humidity sensor system (10) further includes processing circuitry operable to receive output signals from the light detector (22) and from the temperature measurement probe (18) and operable to determine a relative humidity based on the output signals from the light detector (22) and the temperature measurement probe (18).

### FIELD OF THE DISCLOSURE

The present disclosure relates to humidity sensors.

### BACKGROUND

Humidity refers to the water vapor content in air or other gases and can be expressed in a number of ways, including absolute humidity, relative humidity and dew point. Absolute humidity, for example, refers to the ratio of the mass of water vapor to the volume of air or gas. In contrast, relative humidity refers to the ratio of the percentage of water vapor present in the air or gas at a particular temperature and pressure to the maximum amount of water vapor the air or gas can hold at that temperature and pressure.

Some humidity sensors operate based on the absorption of water vapor by organic compounds (e.g., polyimide) and corresponding changes in the property of the organic compounds. Organic compounds such as polyimide, however, may be highly sensitive to variations in the processing conditions, production batch, storage conditions, shelf life and the like. Further, polyimide and other organic compounds may degrade relatively quickly in harsh ambient conditions (e.g., where there is significant sunlight). Even in the absence of these issues, humidity measurements based on polyimide equilibrium absorption can take a relatively long time (e.g., up to several hours), which makes such techniques unsuitable for some applications.

### SUMMARY

The present disclosure describes humidity sensors that incorporate an optical waveguide.

For example, in one aspect, the disclosure describes a humidity sensor system that includes a monolithically integrated semiconductor device. The monolithically integrated semiconductor device includes an optical waveguide, a thermo-electric cooling device, a temperature measurement probe, and control circuitry operable to cause the thermo-electric cooling device to adjust a temperature of the monolithically integrated semiconductor device. The optical waveguide is operable to receive an input optical signal from a light source and to provide an output optical signal for sensing by a light detector. The humidity sensor system further includes processing circuitry operable to receive output signals from the light detector and from the temperature measurement probe and operable to determine a relative humidity based on the output signals from the light detector and the temperature measurement probe.

Some implementations include one or more of the following features. For example, the monolithically integrated semiconductor device can include the processing circuitry and/or the light detector. In some cases, the monolithically integrated semiconductor device includes a silicon substrate. The optical waveguide can includes, for example, a waveguide core, a cladding layer adjacent a first side of the waveguide core, and an isolation layer adjacent a second side of the waveguide core, wherein the isolation layer has an opening therein. In some implementations, the waveguide core is composed of silicon or silicon nitride, the cladding layer is composed of silicon dioxide, and/or the isolation layer is composed of silicon dioxide. The humidity sensor system can be operable for condensation to form in the opening, such that an evanescent field of a light signal propagating along the optical waveguide interacts with the condensation so as to modify a characteristic of the output optical signal measured by the light detector. In some cases, the humidity sensor system is operable to perform a measurement cycle of relative humidity in less than one second.

In another aspect, the disclosure describes a method of using a humidity sensor system that includes a monolithically integrated semiconductor device including an optical waveguide, a thermo-electric cooling device, and a temperature measurement probe. The method includes controlling the thermo-electric cooling device to adjust (e.g., decrease) a temperature of the monolithically integrated semiconductor device, sensing optical signals output from the optical waveguide as the temperature of the monolithically integrated semiconductor device is adjusted, determining a temperature of the monolithically integrated semiconductor device that coincides with a particular change in the sensed optical signals output from the optical waveguide, and determining a relative humidity value based on the determined temperature.

Some implementations include on or more of the following features. For example, controlling the thermo-electric cooling device can include controlling the thermo-electric cooling device to lower the temperature of the monolithically integrated semiconductor device such that condensation is present on the optical waveguide. In some cases, controlling the thermo-electric cooling device includes controlling the thermo-electric cooling device to lower the temperature of the monolithically integrated semiconductor device to about 0° C. or to lower the temperature of the monolithically integrated semiconductor device to about 10° C. below ambient temperature. In some instances, an evanescent field of a light signal propagating along the optical waveguide interacts with the condensation. In some cases, an amplitude of the optical signals output from the optical waveguide decrease as a result of the evanescent field interacting with the condensation. The condensation may be present, for example, in an opening of an isolation layer that is adjacent a core of the optical waveguide. In some instances, the method further includes controlling the thermo-electric cooling device to allow the temperature of the monolithically integrated semiconductor device to increase to ambient temperature.

The disclosure also describes an apparatus including a host device (e.g., a smartphone) that has a display screen and a humidity sensor system.

Various advantages can be provided in some implementations. For example, the humidity sensor system can be relatively compact, making it suitable for integration into host computing devices (e.g., smartphones) in which space is at a premium. Further, in some cases, the full cycle of operation of the sensor occurs on the order of one second or less, thereby allowing determinations of relative humidity do be made very quickly.

Other aspects, features and advantages will be readily apparent from the following detailed description, the accompanying drawings, and the claims.

### BRIEF DESCRIPTION OF THE DRAWINGS

FIG. 1 illustrates an example of a hybrid sensor system including an optical waveguide.

FIG. 2 illustrates further details of a monolithically integrated sensor.

FIG. 3 is a flow chart illustrating a method of operation for the sensor system.

FIGS. 3A 3D show various states of the sensor system.

FIG. 4 illustrates an example of a host device incorporating the hybrid sensor system.

### DETAILED DESCRIPTION

The present disclosure describes humidity sensors that incorporate an optical waveguide. The humidity sensor can be part of a monolithically integrated, CMOS-compatible semiconductor device that uses optical techniques to measure condensation on the sensor, and that is operable to determine the relative humidity based on the measured condensation.

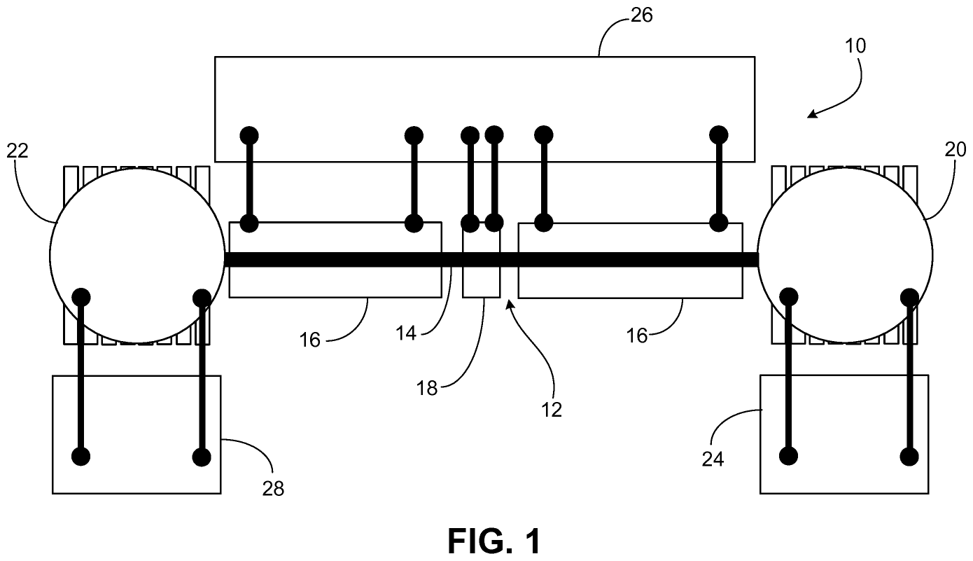

As shown in the example of FIG. 1, a hybrid sensor system 10 includes a monolithically integrated sensor 12 that can be implemented in, or on, a single semiconductor chip. The sensor 12 includes an optical waveguide 14, a thermo-electric cooling (TEC) device 16 and a thermometric (temperature measurement) probe 18, each of which can be formed in, or on, the semiconductor chip.

Light from a light source 20, such as a vertical cavity surface emitting laser (VCSEL), is coupled into the waveguide 14, and light exiting the waveguide 14 is sensed by a light detector 22, such as a photodiode. Other types of light sources (e.g., light emitting diodes (LEDs), infra-red (IR) LEDs, organic LEDs (OLEDs), infra-red (IR) lasers) can be used in some implementations.

Typically, the light source 20 is operable to generate light having a wavelength in the range of 650 nm 1550 nm, although other wavelengths or wavelength ranges may be suitable for some applications. A driver 24 is operable to drive the VCSEL or other light source 20. The waveguide 14 is configured such that the light emitted by the light source 20 and coupled into the waveguide 14 propagates along the waveguide in a direction toward the opposite end of the waveguide. The light detector 22 is operable to sense light of the same wavelength as emitted by the light source 20 and, in some cases, also can be formed in the semiconductor chip.

Thermo-control circuitry 26, which can be implemented in the semiconductor substrate using CMOS-based technology, is operable to control and/or receive signals from the thermo-electric cooling device 16 and the thermometric probe 18. Processing circuitry 28, which also can be implemented in the semiconductor chip using CMOS-based technology, is operable to read and process output signals from the light detector 22. The thermo-control circuitry 26 and/or the thermometric probe 18 can be coupled to the processing circuitry 28 as well.

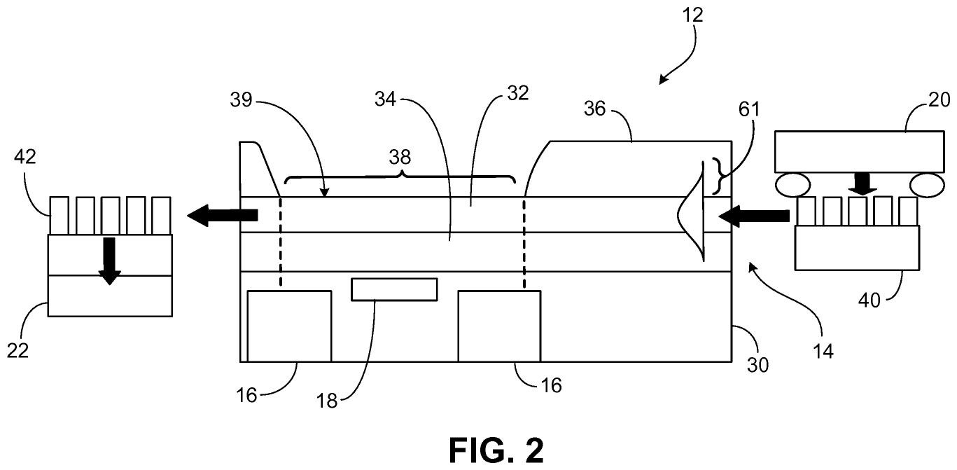

FIG. 2 illustrates further details of the monolithically integrated sensor 12 according to some implementations. As shown in FIG. 2, the thermo-electric cooling device 16 and thermometric probe 18 are formed in or on a silicon substrate 30.

The thermo-electric cooling device 16 can be implemented in various ways. In some cases, the thermo-electric cooling device 16 employs the Peltier effect at a metal/semiconductor junction and is composed of a series of n- and p-type semiconductor elements to lower the operating current of the thermoelectric module. Thus, for example, a bulk BiTe or BiSbTe thermoelectric module can be provided on the silicon substrate 30. In other instances, the thermo-electric cooling device 16 can be implemented as a thin-film superlattice SiGe/Si heterostructure integrated thermionic cooler.

The thermometric probe 18 can be implemented, for example, as a thermocouple which is operable to measure the temperature of the sensor. In some instances, the thermometric probe 18 is a silicon-based thermopile sensor operable to measure differential temperatures. Other implementations can be used for the thermo-electric cooling device 16 or the thermometric probe 18.

The structure for the waveguide 14 is formed on the silicon substrate 30 and includes a core 32, a lower cladding 34 adjacent to and below the core 32, and an isolation layer 36 disposed on part of the upper surface of the core 32. In general, the refractive index of the cladding 34 should be lower than that of the core 32. In the illustrated example, the lower cladding 34 is composed of silicon dioxide (SiO₂), and the core is composed of silicon (Si) or silicon nitride (SiN). The isolation layer 36 can be composed, for example, of SiO₂ as well. The isolation layer 36 defines an opening 38 that serves as a window 39 where condensation (e.g., water drops) may form, for example, when the sensor is cooled.

Light from the light source 20 is coupled into the waveguide 14, for example, using a first grating coupler 40. Likewise, light from the waveguide 14 is coupled to the light detector 22, for example, using a second grating coupler 42. The grating couplers 40, 42 can be implemented, for example, by patterning the ends of the core 32.

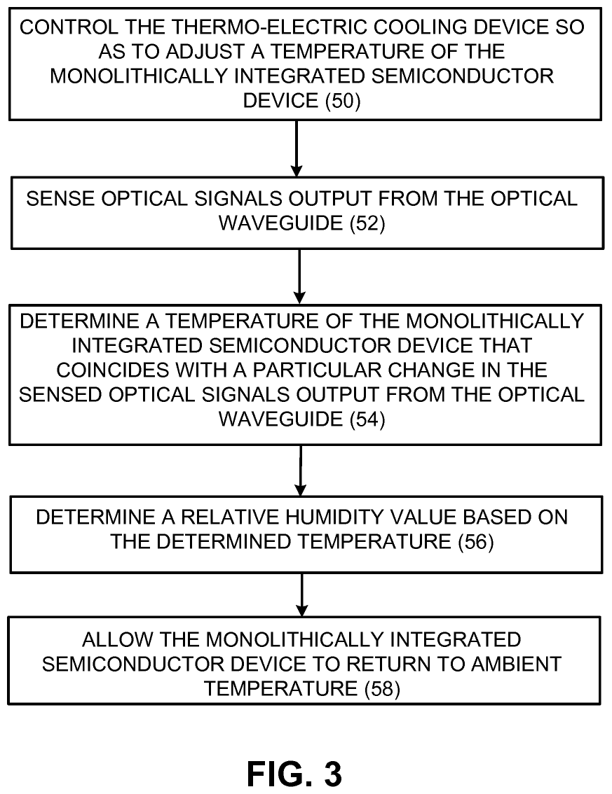

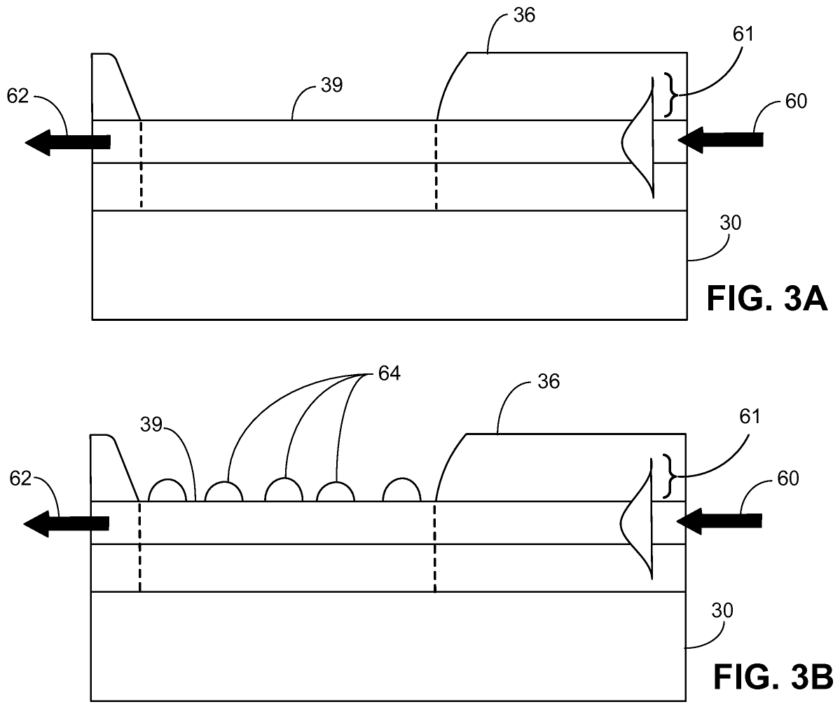

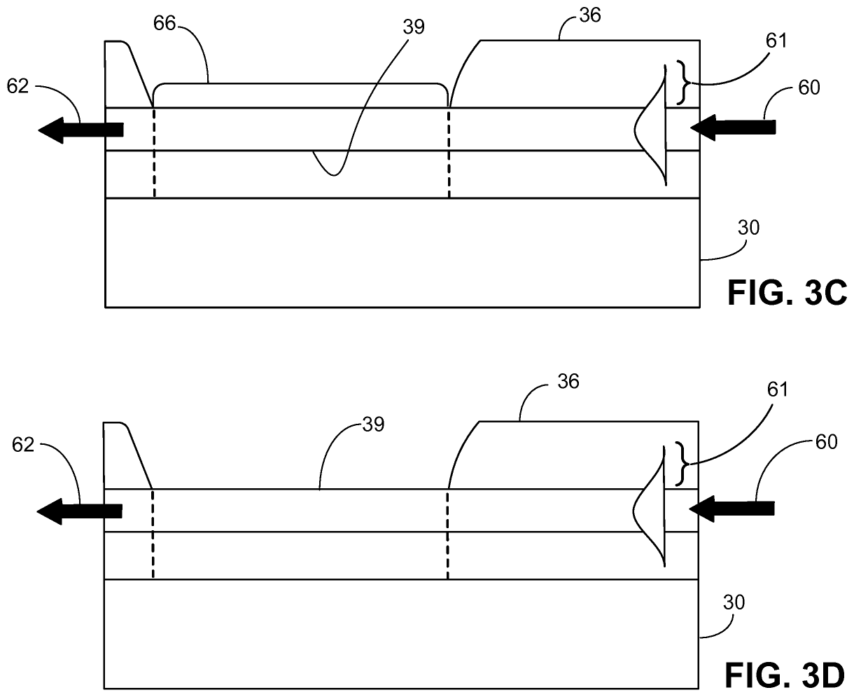

FIG. 3 illustrates a general method of using the sensor system 10. The method includes controlling the thermo-electric cooling device 16 so as to adjust (e.g., decrease) a temperature of the monolithically integrated semiconductor device (50), sensing optical signals output from the optical waveguide 14 as the temperature of the monolithically integrated semiconductor device is adjusted (52), determining a temperature of the monolithically integrated semiconductor device that coincides with a particular change in the sensed optical signals output from the optical waveguide (54), determining a relative humidity value based on the determined temperature (56), and allowing the monolithically integrated semiconductor device to return to ambient temperature (58). The foregoing cycle of operations can be performed repeatedly on an ongoing basis.

Further operational details of the sensor system 10 are explained with reference to FIGS. 3A 3D. FIG. 3A, for example, shows an initial state of the sensor where there is no condensation present on the window 39. Throughout operation, the input light signal 60 is coupled continuously into the waveguide 14, propagates through the waveguide, and an output light signal 62 is detected by the light detector 22. The processing circuitry 28 continuously analyzes the signal output by the detector 62 to identify one or more characteristics (e.g., amplitude) of the output signal, and the thermometric probe 18 continuously measures the temperature of the sensor. As shown in FIG. 3B, in a subsequent state, the control circuitry 26 operates the thermo-electric cooling device 16 so as to cool the sensor probe, which causes condensation (e.g., dew drops) 64 to form on the window 39. As the thermo-electric cooling device 16 continues to cool the sensor, condensation continues to form until there is a layer 66 of condensation (e.g., water) covering the window 39 (see FIG. 3C). In some cases, the sensor is cooled down to about 0° C.; in other implementations, it may be sufficient to cool the sensor down to about 10 degrees Celsius below ambient temperature. Once the sensor is cooled, the control circuitry 26 turns off the thermo-electric cooling device 16 so as to allow the sensor to return to ambient temperature and so that the condensation evaporates from the sensor's window 39 (see FIG. 3D). In some implementations, the control circuitry 26 reverses the polarity of the thermo-electric cooling device 16 so as to heat the sensor until it returns to the ambient temperature. In some instances, the full cycle of operation (i.e., FIG. 3A FIG. 3D) occurs on the order of one second, and in some cases, may be even less than one second.

As the evanescent field 61 of the light signal 68 propagates along the waveguide 14, if condensation 64, 66 is present on the window 39, the light signal interacts with the condensation. As a result, one or more characteristics (e.g., amplitude) of the light signal detected by the light detector 22 change. As the processing circuitry 28 analyzes the output signal from the light detector 22, the processing circuitry looks for a particular change in the signal's amplitude. For example, the processing circuitry 28 can continuously analyze the detector's output signal to determine whether a specified absolute (or relative) drop from the peak amplitude of the detected signal has occurred. In some instances, the processing circuitry 28 determines whether at least a specified change (e.g., several tenths dB) in the detected optical power has occurred. When the processing circuitry 28 determines that at least the specified amount of change has occurred, the processing circuitry stores the temperature (as determined by the thermometric probe 18) that corresponds to the same time at which the specified change in the amplitude of the detector's output occurred. The processing circuitry 28 then can determine the relative humidity based on the sensor's temperature using, for example, a previously determined mathematical equation expressing the relationship between the sensor temperature and the relative humidity. For example, in some implementations, an approximation, known as the Magnus formula, can be used for the relative humidity (RH) can be used:

$$γ ( T , R H ) = ln ( \frac{RH}{100} ) + \frac{b T}{c + T} ;$$

$${T}_{d p} = \frac{c γ ( T , RH \}}{b - γ ( T , R H )} ;$$

where T_{dp} is the dew point, and T is the actual air temperature (in ° C.). Other equations or relationships can be used as well.

The mathematical equation or other relationship can be implemented, for example, in software associated with the processing circuitry 28. In some cases, the relationship between the sensor temperature and the relative humidity is stored as a look-up table in memory associated with the processing circuitry 28.

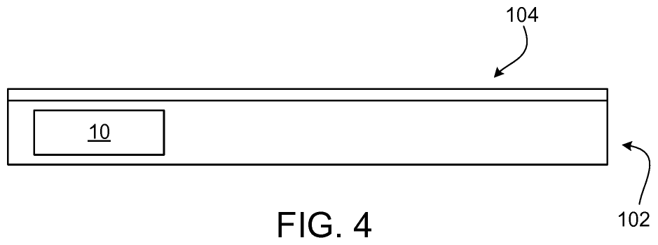

The monolithically integrated relative humidity sensor can be used in a wide range of applications. For example, as shown in FIG. 4, the sensor 10 can be integrated into a host device 102 such as a portable computing device (e.g., a smartphone, personal digital assistant (PDA), laptop or wearable computing device) that may have with networking capability. The relative humidity sensor also may be integrated into other consumer products such as headphones and also can be used in automotive applications. In some instances, the relative humidity value determined by the sensor can be displayed, for example, on a display screen 104 of the smartphone or other host device. Further, in some cases, the relative humidity value may be used by the host device's to control or adjust a feature of some other unit in the host device.

Various modifications will be readily apparent from the foregoing description. Accordingly, other implementations are within the scope of the claims.

1. A humidity sensor system comprising:
a monolithically integrated semiconductor device including:
an optical waveguide;
a thermo-electric cooling device;
a temperature measurement probe; and
control circuitry operable to cause the thermo-electric cooling device to adjust a temperature of the monolithically integrated semiconductor device;
wherein the optical waveguide is operable to receive an input optical signal from a light source and to provide an output optical signal for sensing by a light detector,
the humidity sensor system further including processing circuitry operable to receive output signals from the light detector and from the temperature measurement probe and operable to determine a relative humidity based on the output signals from the light detector and the temperature measurement probe.

2. The humidity sensor system of claim 1 wherein the monolithically integrated semiconductor device includes the processing circuitry.

3. The humidity sensor system of claim 1 wherein the monolithically integrated semiconductor device includes the light detector.

4. The humidity sensor system of claim 1 wherein the monolithically integrated semiconductor device includes a silicon substrate.

5. The humidity sensor system of claim 1 wherein the optical waveguide includes:
a waveguide core;
a cladding layer adjacent a first side of the waveguide core;
an isolation layer adjacent a second side of the waveguide core, wherein the isolation layer has an opening therein.

6. The humidity sensor system of claim 5 operable for condensation to form in the opening, such that an evanescent field of a light signal propagating along the optical waveguide interacts with the condensation so as to modify a characteristic of the output optical signal measured by the light detector.

7. The humidity sensor system of claim 5 wherein the waveguide core comprises silicon.

8. The humidity sensor system of claim 5 wherein the waveguide core is composed of silicon or silicon nitride.

9. The humidity sensor system of claim 5 wherein the cladding layer is composed of silicon dioxide.

10. The humidity sensor system of claim 5 wherein the isolation layer is composed of silicon dioxide.

11. The humidity sensor system of claim 1 operable to perform a measurement cycle of relative humidity in less than one second.

12. A method of using a humidity sensor system comprising a monolithically integrated semiconductor device that includes an optical waveguide, a thermo-electric cooling device, and a temperature measurement probe, the method comprising:
controlling the thermo-electric cooling device to adjust a temperature of the monolithically integrated semiconductor device;
sensing optical signals output from the optical waveguide as the temperature of the monolithically integrated semiconductor device is adjusted;
determining a temperature of the monolithically integrated semiconductor device that coincides with a particular change in the sensed optical signals output from the optical waveguide; and
determining a relative humidity value based on the determined temperature.

13. The method of claim 12 wherein controlling the thermo-electric cooling device includes controlling the thermo-electric cooling device to lower the temperature of the monolithically integrated semiconductor device such that condensation is present on the optical waveguide.

14. The method of claim 12 wherein controlling the thermo-electric cooling device includes controlling the thermo-electric cooling device to lower the temperature of the monolithically integrated semiconductor device to about 0° C.

15. The method of claim 12 wherein controlling the thermo-electric cooling device includes controlling the thermo-electric cooling device to lower the temperature of the monolithically integrated semiconductor device to about 10° C. below ambient temperature.

16. The method of claim 13 wherein an evanescent field of a light signal propagating along the optical waveguide interacts with the condensation.

17. The method of claim 16 wherein an amplitude of the optical signals output from the optical waveguide decrease as a result of the evanescent field interacting with the condensation.

18. The method of claim 13 wherein the condensation is present in an opening of an isolation layer that is adjacent a core of the optical waveguide.

19. The method of claim 13 further including controlling the thermo-electric cooling device to allow the temperature of the monolithically integrated semiconductor device to increase to ambient temperature.

20. An apparatus comprising:
a host device including a display screen,
the host device further including the humidity sensor system of claim 1.
